(19) United States
(12) Patent Application Publication
(10) Pub. No.: US 2014/0340847 A1
(43) Pub. Date: Nov. 20, 2014

(54) SUBSTRATE UNIT AND ELECTRONIC DEVICE

(71) Applicant: FUJITSU LIMITED, Kawasaki-shi (JP)

(72) Inventors: Yoshihisa IWAKIRI, Kawasaki (JP); Jie WEI, Hachioji (JP); Keizou Takemura, Kawasaki (JP); Mitsutaka YAMADA, Atsugi (JP)

(73) Assignee: FUJITSU LIMITED, Kawasaki-shi (JP)

(21) Appl. No.: 14/257,104

(22) Filed: Apr. 21, 2014

(30) Foreign Application Priority Data
May 14, 2013 (JP) 2013-102549

(51) Int. Cl. H05K 7/20

(52) U.S. Cl. CPC H05K 7/20218
USPC 361/699

(57) ABSTRACT

A substrate unit includes: a substrate arranged with a first heat generating element on one surface and a second heat generating element on the other surface; a first cooler that is arranged on one surface side of the substrate and that is in contact with the first heat generating element; a second cooler that is arranged on the other surface side of the substrate and that is in contact with the second heat generating element; a supply port provided in the first cooler, the supply port supplying the coolant to the first cooler; a discharge port provided in the first cooler, the discharge port discharging the coolant in the first cooler; and transport tubes that are connected to the first cooler and the second cooler, the transport tubes allowing the coolant to be transported between the first cooler the second cooler.

### CROSS-REFERENCE TO RELATED APPLICATION

This application is based upon and claims the benefit of priority of the prior Japanese Patent Application No. 2013-102549, filed on May 14, 2013, the entire contents of which are incorporated herein by reference.

### FIELD

The embodiments discussed herein are related to a substrate unit and an electronic device.

### BACKGROUND

A structure in which a heat generating element mounted on a substrate is cooled with a cooling plate, through the inside of which a coolant (a liquid refrigerant) flows, is adopted in some cases.

Furthermore, there are cases in which a heat generating component is mounted on both sides of a substrate. Moreover, there are cases in which a plurality of substrates is provided in an electronic device.

The followings are reference documents:

[Document 1] Japanese Laid-open Patent Publication No. 09-214161 and

[Document 2] Japanese Laid-open Patent Publication No. 08-139481.

### SUMMARY

According to an aspect of the invention, a substrate unit includes: a substrate arranged with a first heat generating element on one surface and a second heat generating element on the other surface; a first cooler that is arranged on one surface side of the substrate and that is in contact with the first heat generating element, the first cooler having a coolant flowing therein; a second cooler that is arranged on the other surface side of the substrate and that is in contact with the second heat generating element, the second cooler having the coolant flowing therein; a supply port provided in the first cooler, the supply port supplying the coolant to the first cooler; a discharge port provided in the first cooler, the discharge port discharging the coolant in the first cooler; and transport tubes that are connected to the first cooler and the second cooler, the transport tubes allowing the coolant to be transported between the first cooler the second cooler.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A is a front view illustrating a substrate unit of a first embodiment together with a system substrate;

FIG. 1B is a cross-sectional view taken along the line 1B-1B of FIG. 1A that illustrates the substrate unit of the first embodiment together with the system substrate;

FIG. 1C is a cross-sectional view taken along the line 1C-1C of FIG. 1A that illustrates the substrate unit of the first embodiment together with the system substrate;

FIG. 2A is a front view illustrating a cooling structure of the first embodiment;

FIG. 2B is a plan view illustrating the cooling structure of the first embodiment;

FIG. 2C is a side view illustrating the cooling structure of the first embodiment;

FIG. 3 is a cross-sectional view illustrating a cooling-liquid communicating member of the first embodiment in a non-connected state;

FIG. 4 is a cross-sectional view illustrating the cooling-liquid communicating member of the first embodiment in a connected state;

FIG. 5 is a perspective view illustrating a system substrate body of the first embodiment;

FIG. 6 is a plan view illustrating the system substrate body of the first embodiment;

FIG. 7 is a plan view illustrating an electronic device of the first embodiment;

FIG. 8 is a cross-sectional view that is a section similar to that of FIG. 1B illustrating a substrate unit of a second embodiment together with the system substrate;

FIG. 9 is a cross-sectional view that is a section similar to that of FIG. 1C illustrating a substrate unit of a third embodiment together with the system substrate;

FIG. 10 is a cross-sectional view that is a section similar to that of FIG. 1C illustrating a substrate unit of a fourth embodiment together with the system substrate; and

FIG. 11 is a cross-sectional view that is a section similar to that of FIG. 1B illustrating a substrate unit of a fifth embodiment together with the system substrate.

### DESCRIPTION OF EMBODIMENTS

A first embodiment will be described in detail with reference to the drawings.

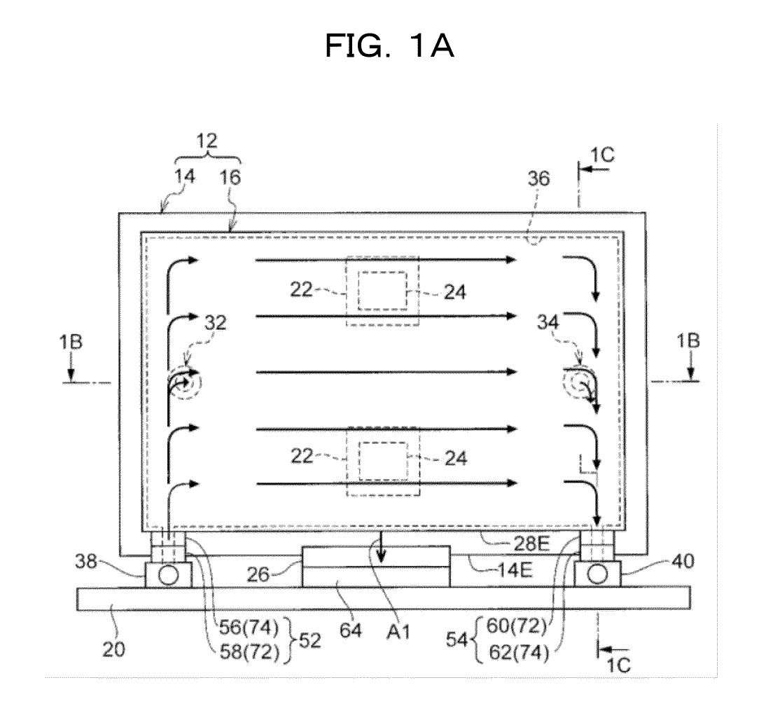

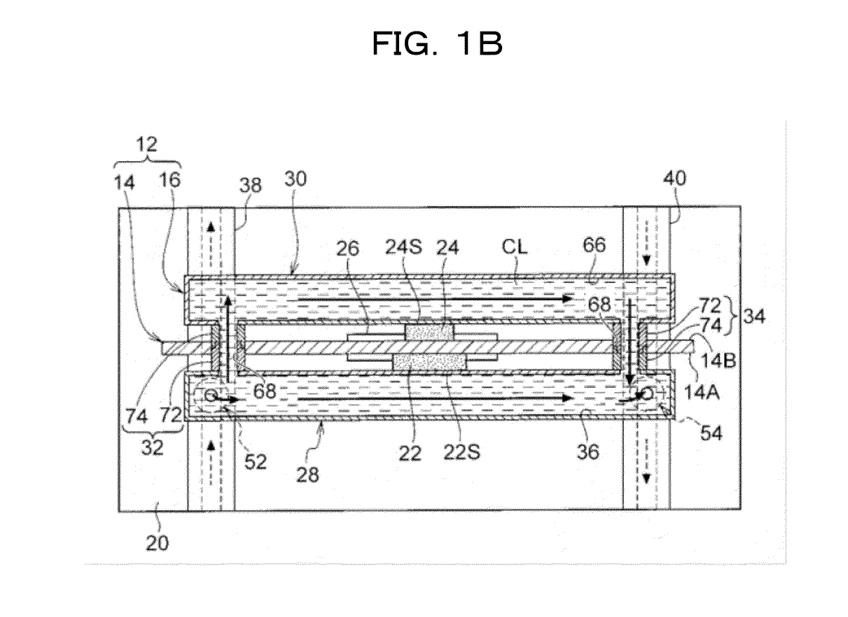

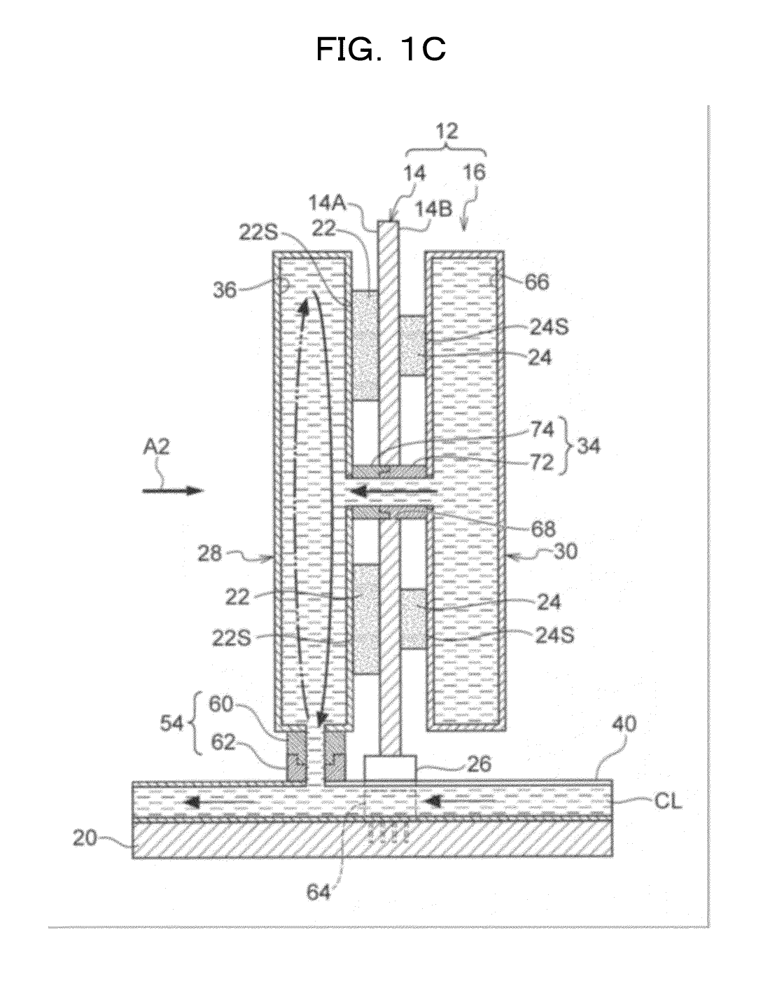

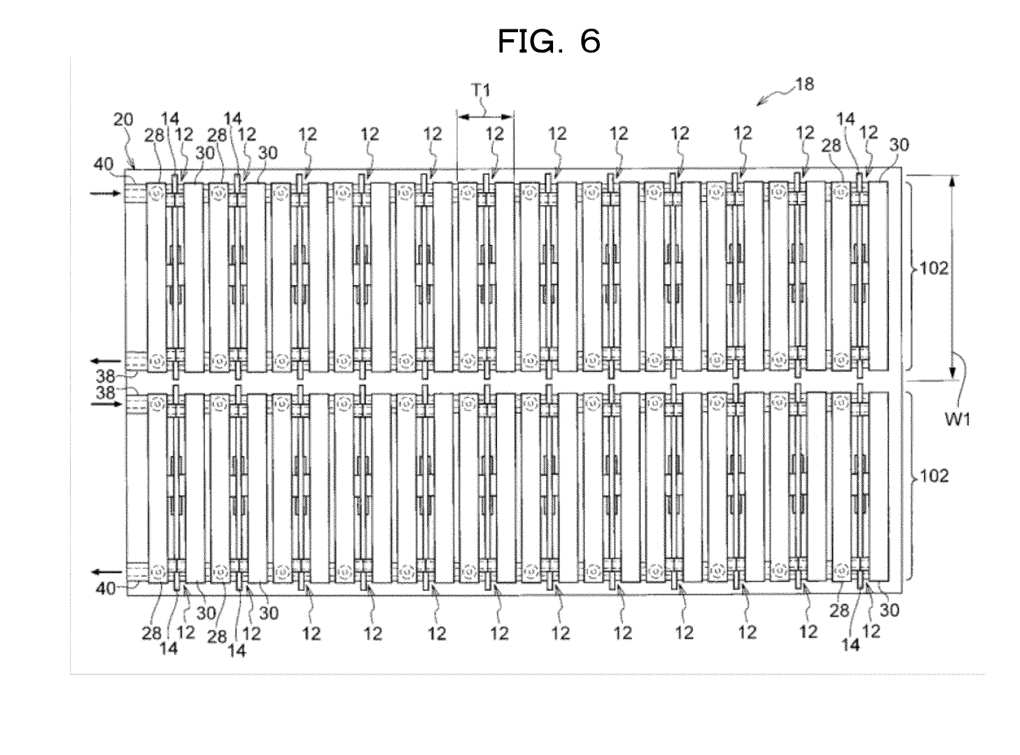

A substrate unit 12 of the first embodiment is illustrated in FIGS. 1A to 1C. The substrate unit 12 includes a package substrate 14 and a cooling structure 16. Furthermore, a system substrate body 18 of the first embodiment is illustrated in FIGS. 5 and 6. The system substrate body 18 includes a system substrate 20 and a plurality of substrate units 12. The package substrate 14 is an example of the substrate.

As can be seen in FIGS. 1B and 1C, the package substrate 14 has a tabular shape. First heat generating elements 22 are mounted on one surface 14A of the package substrate 14. Note that although FIG. 1A and FIG. 1C each illustrate two first heat generating elements 22, one or three or more first heat generating elements 22 may be mounted on the one surface 14A.

Second heat generating elements 24 are mounted on the other surface 14B of the package substrate 14. Note that although FIG. 1A and FIG. 1C each illustrate two second heat generating elements 24, one second heat generating element 24 or three or more plurality of second heat generating elements 24 may be mounted on the other surface 14B.

An integrated circuit and other electronic components may be cited as specific examples of the first heat generating element 22 and the second heat generating element 24; however, in short, the first heat generating element 22 and the second heat generating element 24 may be any kind of elements that generate heat and that are mounted on the package substrate 14.

Circuit patterns that electrically connect the first heat generating elements 22, the second heat generating elements 24, and other electronic components to each other are formed on the package substrate 14. Furthermore, an electrical connector 26 that electrically connects the package substrate 14 to an external device (the system substrate 20 in the first embodiment) is provided at an edge portion 14E of the package substrate 14 (the edge portion of the package substrate 14 on the lower side in FIG. 1A). As will be described later, the electrical connector 26 is moved in the direction of the arrow A1 so as to approach an external device connector 64 (see FIG. 1A) and the electrical connector 26 is connected to the external device connector 64. The electrical connector 26 is an example of an electric connection member.

The cooling structure 16 includes a first coolant member 28, a second coolant member 30, and coolant transport members (transport tubes) 32 and 34. The first coolant member 28 is an example of a first cooling member. The second coolant member 30 is an example of a second cooling member. The coolant transport members 32 and 34 are examples of a connection member.

The first coolant member 28 has a hollow tabular shape. Moreover, the first coolant member 28 is formed with a size that allows the first coolant member 28 to be in contact with the entire surfaces on the other side (other surface 22S) of the two first heat generating elements 22 with respect to the surfaces of the two first heat generating elements 22 on the package substrate 14 side. In the first embodiment, the size of the first coolant member 28 is smaller than the size of the package substrate 14 when viewed in a direction normal to the package substrate 14 (in a direction of the arrow A2 in FIG. 1C).

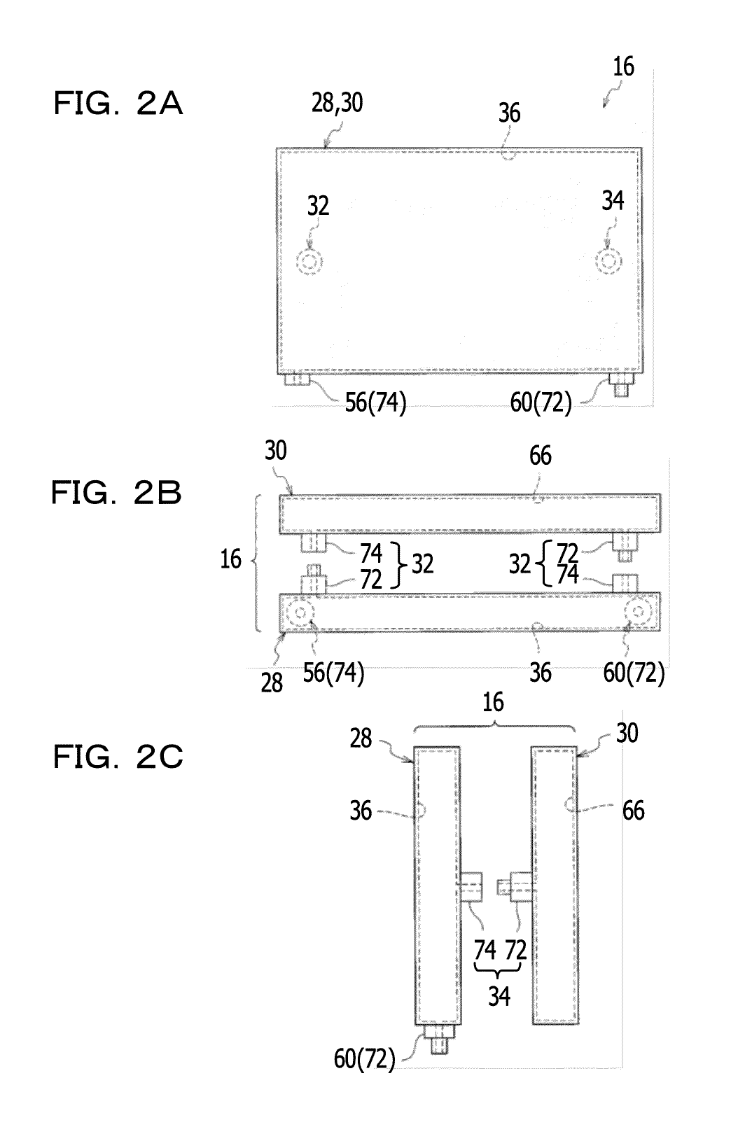

As illustrated in FIGS. 2B and 2C, a flow space 36, allowing a liquid to flow therein, is formed in an intermediate portion of the first coolant member 28 in the plate thickness direction. Particularly, in the first embodiment, as can been seen in FIG. 1A, the flow space 36 is formed with a shape that overlaps the entire surfaces of the two first heat generating elements 22 when viewed in the direction that is normal to the package substrate 14 (in the direction of the arrow A2).

Furthermore, the flow space 36 is closed at the outer edge portion of the first coolant member 28 such that leakage of liquid is suppressed. A coolant CL flows in the flow space 36. Water, oil, antifreeze, or the like may be used as the coolant CL.

Note that, as described above, when there are plural first heat generating elements 22, for example, the first coolant member 28 may be formed with a shape that allows a single first coolant member 28 to be in contact with all of the first heat generating elements 22. Furthermore, the first coolant member 28 may be divided into a plurality of first coolant members 28 such that each first heat generating element 22 (or each group of first heat generating elements 22 when grouped) is in contact with the corresponding first coolant member 28. When the first coolant member 28 is divided as above, the first coolant members 28 may be interconnected with each other so that the coolant CL flows in each of the first coolant members 28.

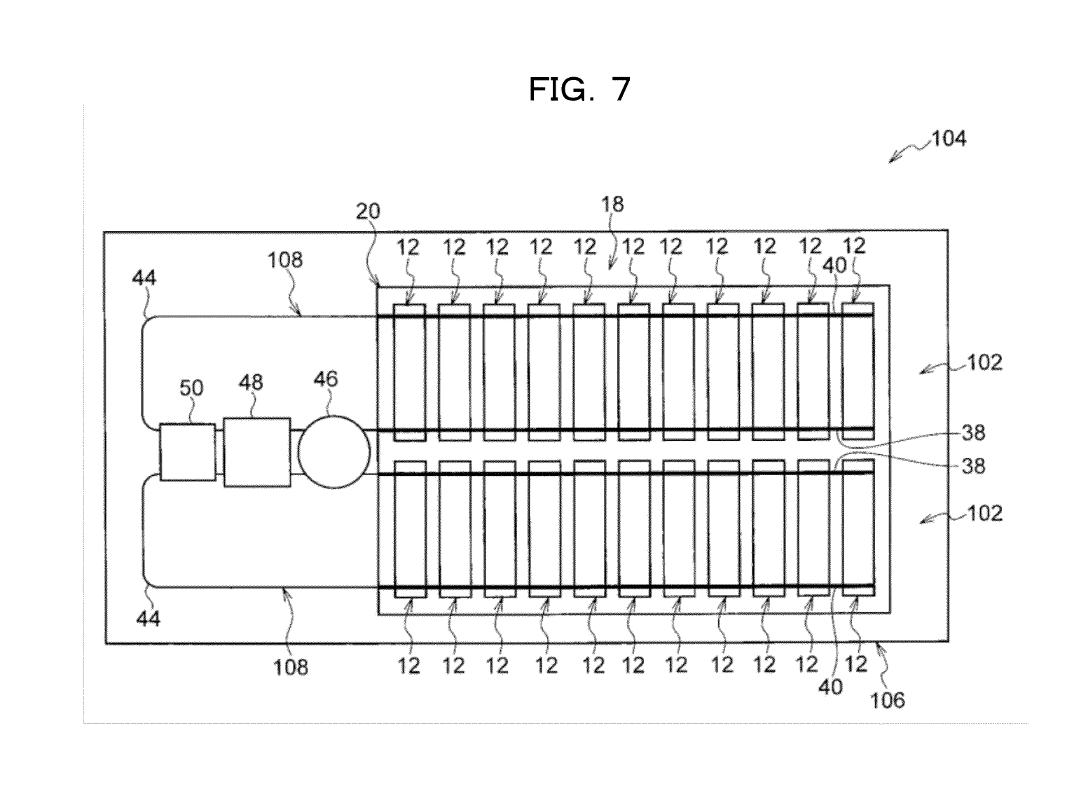

The system substrate 20 is provided with supply passages 38 and discharge passages 40 of the coolant CL. As will be described later, each supply passage 38 and each discharge passage 40 are connected to a corresponding circulation passage 44 (see FIG. 7) to allow circulation of the coolant CL.

A coolant supply member 52 is provided between the first coolant member 28 and the supply passage 38. Furthermore, a coolant discharge member 54 is provided between the first coolant member 28 and the discharge passage 40.

The coolant supply member 52 includes a supply-side connection member 56 provided in a supply port at an edge portion 28E of the first coolant member 28 and a supply-purpose connection member 58 that is provided in the supply passage 38 of the system substrate 20. Furthermore, the coolant discharge member 54 includes a discharge-side connection member 60 that is provided in the discharge port at the edge portion 28E of the first coolant member 28 and a discharge-purpose connection member 62 that is provided in the discharge passage 40 of the system substrate 20.

The supply-side connection member 56 is connected to the supply-purpose connection member 58, and the discharge-side connection member 60 is connected to the discharge-purpose connection member 62. Hereinafter, the state described above in which the supply-side connection member 56 is connected to the supply-purpose connection member 58 and the discharge-side connection member 60 is connected to the discharge-purpose connection member 62 is simply referred to as a “connected state”. The connected state allows the coolant CL supplied from the supply passage 38 to flow into the flow space 36 through the coolant supply member 52 and, further, allows the coolant CL in the flow space 36 to be discharged into the discharge passage 40 through the coolant discharge member 54.

In the illustrated example, the supply-side connection member 56 and the discharge-side connection member 60 are provided in the same edge portion 28E of the first coolant member 28. Furthermore, a direction in which the supply-side connection member 56 is connected to the supply-purpose connection member 58 is the same as a direction in which the electrical connector 26 is connected to the external device connector 64 (the direction of the arrow A1 illustrated in FIG. 1A). Furthermore, a direction in which the discharge-side connection member 60 is connected to the discharge-purpose connection member 62 is also the same as the direction in which the electrical connector 26 is connected to the external device connector 64 (the direction of the arrow A1).

Furthermore, when connecting the supply-side connection member 56 to the supply-purpose connection member 58, the connection position and the displacement amount of the supply-side connection member 56 are set so that when the electrical connector 26 is connected to the external device connector 64, the supply-side connection member 56 is connected to the supply-purpose connection member 58 at the same time.

Moreover, when connecting the discharge-side connection member 60 to the discharge-purpose connection member 62, the connection position and the displacement amount of the discharge-side connection member 60 are set so that when the electrical connector 26 is connected to the external device connector 64, the discharge-side connection member 60 is connected to the discharge-purpose connection member 62 at the same time.

The second coolant member 30 has a hollow tabular shape. Moreover, the second coolant member 30 is formed with a size that allows the second coolant member 30 to be in contact with the entire surfaces on the other side (other surface 24S) of the two second heat generating elements 24 with respect to the surfaces of the two second heat generating elements 24 on the package substrate 14 side. In the first embodiment, the size of the second coolant member 30 is smaller than the size of the package substrate 14 when viewed in the direction normal to the package substrate 14 (in the direction of the arrow A2).

As illustrated in FIGS. 2B and 2C, a flow space 66, allowing a liquid to flow therein, is formed in an intermediate portion of the second coolant member 30 in the plate thickness direction. Particularly in the first embodiment, as can been seen in FIG. 1A, the flow space 66 is formed with a shape that overlaps the entire surfaces of the two second heat generating elements 24 when viewed in the direction that is normal to the package substrate 14 (in the direction of the arrow A2). Furthermore, the flow space 66 is closed at the outer edge portion of the second coolant member 30 such that leakage of liquid is suppressed.

Two coolant transport members 32 and 34 are arranged between the first coolant member 28 and the second coolant member 30. The coolant transport members 32 and 34 allow the coolant CL to be transported between the flow space 36 of the first coolant member 28 and the flow space 66 of the second coolant member 30.

Through holes 68 are formed in the package substrate 14 at positions corresponding to the positions of the coolant transport members 32 and 34. The first coolant member 28 and the second coolant member 30 are connected to each other with the coolant transport members 32 and 34 while the coolant transport members 32 and 34 are positioned in the through holes 68.

In the illustrated example, as can be seen in FIG. 1A, the coolant transport member 32 is provided above the coolant supply member 52, and the coolant transport member 34 is provided above the coolant discharge member 54. Accordingly, a portion of the coolant CL supplied to the first coolant member 28 flows into the second coolant member 30 through the coolant transport member 32. Furthermore, the coolant CL in the second coolant member 30 flows into the first coolant member 28 through the coolant transport member 34.

The height (the position in the up-down direction of FIG. 1A) at which each of the coolant transport members 32 and 34 are arranged is not limited to a specific height; however, in the illustrated example, the coolant transport members 32 and 34 are both provided midway along the first coolant member 28 in the height direction and at the same height. Accordingly, compared with a structure in which the position of each of the coolant transport members 32 and 34 is at the upper portion or the lower portion in the height direction, the flow of the coolant CL in the horizontal direction is smooth in the flow space 66 of the second coolant member 30. When further compared with a structure in which the height of each of the coolant transport members 32 and 34 are different, the flow of the coolant CL in the horizontal direction is smooth in the flow space 66 of the second coolant member 30.

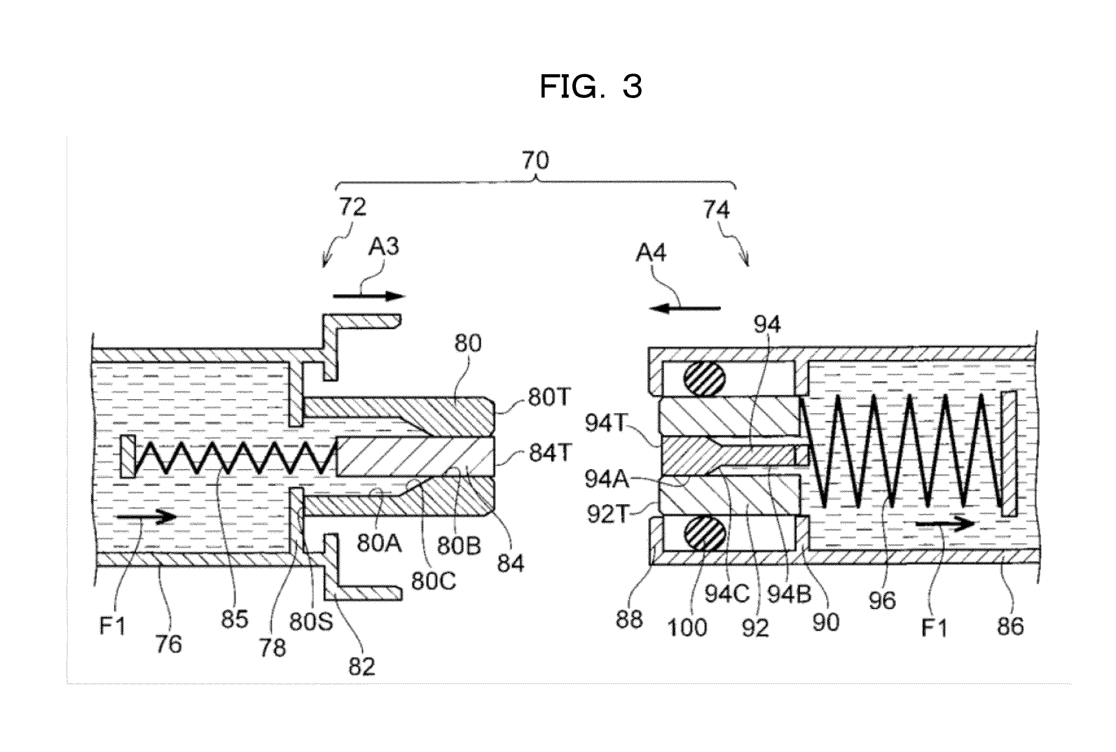

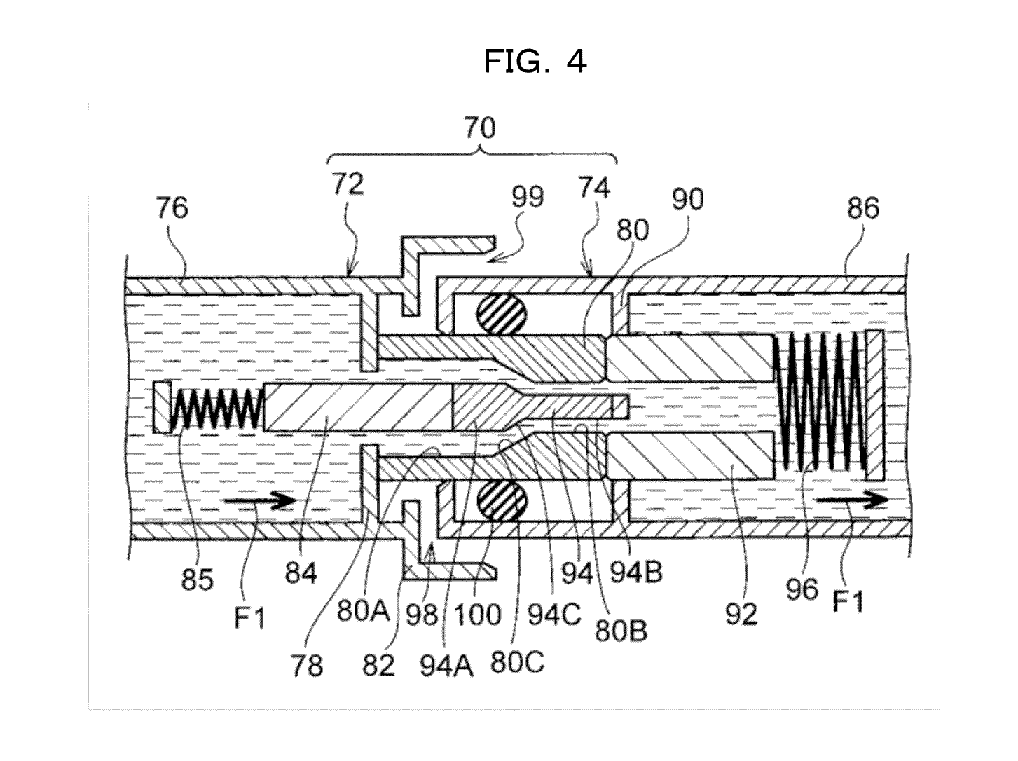

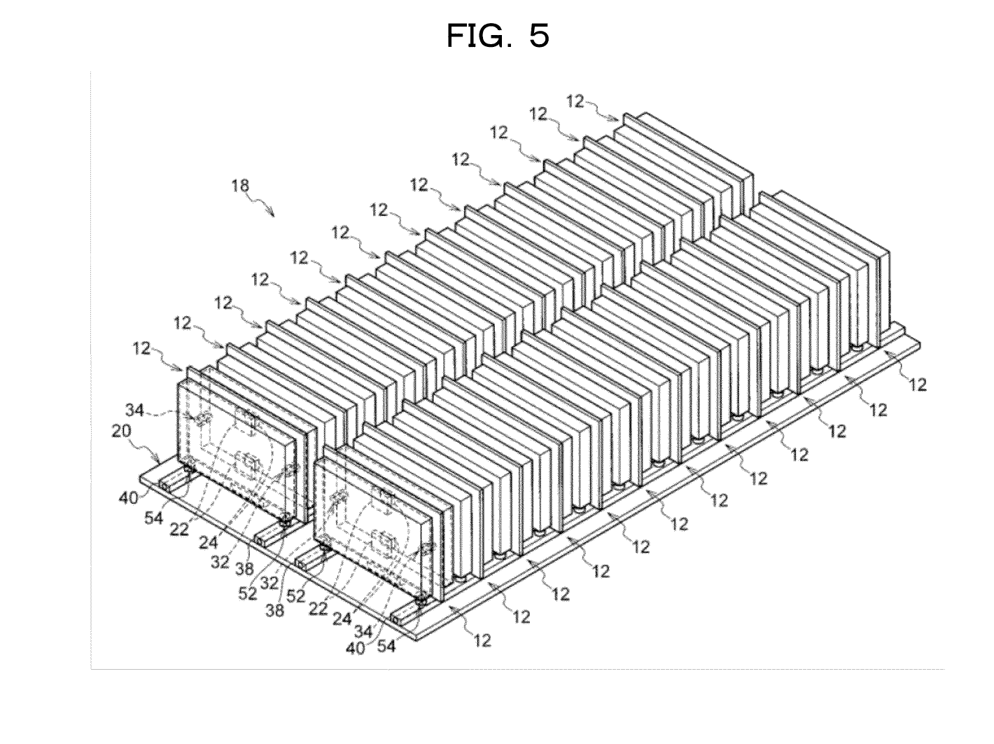

The coolant supply member 52, the coolant discharge member 54, and the coolant transport members 32 and 34 have the same basic structure. Hereinafter, the coolant supply member 52, the coolant discharge member 54, and the coolant transport members 32 and 34 are each referred to as a cooling-liquid communicating member 70. Referring to FIGS. 3 and 4, the structure of the cooling-liquid communicating member 70 will be described.

The cooling-liquid communicating member 70 includes a connecting plug 72 that is positioned upstream in the flow direction of the coolant CL and a connecting socket 74 that is positioned downstream in the flow direction of the coolant CL. Hereinafter, upstream and downstream in the flow direction of the coolant (in the direction of the arrow F1) are simply referred to as “upstream” and “downstream”, respectively.

The connecting plug 72 includes a cylindrical plug outer cylinder 76. There is an annular plug outer ring 78 downstream of the plug outer cylinder 76.

Furthermore a cylindrical plug inner cylinder 80 that has a smaller diameter than that of the plug outer cylinder 76 is arranged downstream of the plug outer ring 78. While an end face 80S of the plug inner cylinder 80 on the upstream side is in contact with the plug outer ring 78, the plug inner cylinder 80 is held by a holding member so that the plug inner cylinder 80 may be displaced in the diameter direction.

A receiving cylinder 82 that partially receives a socket outer cylinder 86 when the connecting plug 72 is connected to the connecting socket 74 is formed downstream of the plug outer cylinder 76.

The inner peripheral surface of the plug inner cylinder 80 includes a large-diameter surface 80A on the upstream side, a small-diameter surface 80B on the downstream side, and a tapered surface 80C that continues from the large-diameter surface 80A to the small-diameter surface 80B in which the inside diameter is gradually reduced from the large-diameter surface 80A to the small-diameter surface 80B.

A columnar plug pin 84 that has an outside diameter that is equal to the inside diameter of the small-diameter surface 80B of the plug inner cylinder 80 is arranged inside the plug inner cylinder 80. The plug pin 84 is biased toward the downstream side with a plug-side spring 85 that is arranged inside the plug outer cylinder 76. However, the displacement of the plug pin 84 toward the downstream side is restricted by a stopper at a position where an end face 84T of the plug pin 84 on the downstream side becomes substantially flush with an end face 80T of the plug inner cylinder 80 on the downstream side. In such a state, the outer peripheral surface of the plug pin 84 is in contact with the small-diameter surface 80B of the plug inner cylinder 80 without any gap therebetween; accordingly, the flow of the coolant CL between the plug inner cylinder 80 and the plug pin 84 is blocked.

Conversely, when the plug pin 84 counters the biasing force of the plug-side spring 85 and moves upstream and when the outer peripheral surface of the plug pin 84 becomes separated from the small-diameter surface 80B of the plug outer cylinder 76, the coolant CL will be allowed to flow between the plug inner cylinder 80 and the plug pin 84.

The connecting socket 74 includes the cylindrical socket outer cylinder 86. There is an annular socket ring 88 on the upstream side of the socket outer cylinder 86 and an annular guide ring 90 is fixed in the socket outer cylinder 86 at a position downstream of the socket ring 88.

A socket inner cylinder 92 that has a smaller diameter than the diameter of the socket outer cylinder 86 is arranged between the socket ring 88 and the guide ring 90.

A substantially columnar socket pin 94 is accommodated inside the socket inner cylinder 92 and is fixed to the socket outer cylinder 86 and other components such that the socket pin 94 is unable to move in the flow direction of the coolant CL. The outer peripheral surface of the socket pin 94 includes a large-diameter portion 94A on the upstream side, a small-diameter portion 94B on the downstream side, and a tapered portion 94C that continues from the large-diameter portion 94A to the small-diameter portion 94B in which the outside diameter is gradually reduced from the large-diameter portion 94A to the small-diameter portion 94B.

The socket inner cylinder 92 is biased toward the upstream side with a socket-side spring 96 that is arranged inside the socket outer cylinder 86. However, the displacement of the socket inner cylinder 92 toward the upstream side is restricted by a stopper at a position where an end portion 92T of the socket inner cylinder 92 on the upstream side becomes substantially flush with an end portion 94T of the socket pin 94 on the upstream side. In such a state, the large-diameter portion 94A of the socket pin 94 is in contact with the inner peripheral surface of the socket inner cylinder 92 without any gap therebetween; accordingly, the flow of the coolant CL between the socket inner cylinder 92 and the socket pin 94 is blocked.

Conversely, when the socket inner cylinder 92 counters the biasing force of the socket-side spring 96 and moves downstream and when the inner peripheral surface of the socket inner cylinder 92 becomes separated from the outer peripheral portion of the socket pin 94, the coolant CL will be allowed to flow between the socket inner cylinder 92 and the socket pin 94.

Note that the outer peripheral surface of the socket inner cylinder 92 is in contact with the inner peripheral surface of the guide ring 90. Accordingly, the motion of the socket inner cylinder 92 is guided by the guide ring 90.

When the connecting plug 72 and the connecting socket 74 are connected, as illustrated in FIG. 4, the connecting plug 72 and the connecting socket 74 are moved close to each other. In other words, the connecting plug 72 is moved in the direction of the arrow A3 or the connecting socket 74 is moved in the direction of the arrow A4 (alternatively, both may be moved). Then, the end portion of the plug inner cylinder 80 on the downstream side and the end portion of the socket inner cylinder 92 on the upstream side come into contact with each other, and the end portion of the plug pin 84 on the downstream side and the end portion of the socket pin 94 on the upstream side come into contact with each other.

When the connecting plug 72 and the connecting socket 74 are further relatively moved in the direction that makes the two close to each other, the plug inner cylinder 80 counters the biasing force of the socket-side spring 96 and moves the socket inner cylinder 92 toward the downstream side. Furthermore, the socket pin 94 counters the biasing force of the plug-side spring 85 and moves the plug pin 84 toward the upstream side. Furthermore, as can be seen in FIG. 4, when the tapered portion 94C of the socket pin 94 is pushed into a position where the tapered portion 94C of the socket pin 94 faces the tapered surface 80C of the plug inner cylinder 80, a state is obtained in which the coolant CL is allowed to flow from the plug outer cylinder 76 through the plug inner cylinder 80 and the socket inner cylinder 92 to the socket outer cylinder 86. This state is the connected state.

In the connected state, the connecting plug 72 and the connecting socket 74 are locked to each other with a lock mechanism so that they are not separated from each other. The locked state may be canceled by operating a cancellation member.

Note that, as can be seen in FIG. 4, a gap 98 is created between the receiving cylinder 82 and the socket ring 88 in the connected state. This gap 98 allows the deviation of the connected position in the direction of connection (the directions of the arrows A3 and A4) to be tolerated. Furthermore, a gap 99 is also created between the socket outer cylinder 86 and the receiving cylinder 82 in the radial direction of the socket outer cylinder 86 (in a perpendicular direction when viewed in the coolant flow direction). Furthermore, the plug inner cylinder 80 may be moved with respect to the plug outer cylinder 76 in a perpendicular direction when viewed in the coolant flow direction. When the connecting plug 72 and the connecting socket 74 are connected, the plug inner cylinder 80 may be kept at an appropriate connection position while misalignment of the connecting plug 72 and the connecting socket 74 in the radial direction are tolerated.

Note that a seal ring 100 is arranged between the socket ring 88 and the guide ring 90. The seal ring 100 is formed in an annular shape from a material with elasticity such as rubber, resin, or the like and is closely attached to the inner peripheral surface of the socket outer cylinder 86.

Furthermore, the socket inner cylinder 92 and the plug inner cylinder 80 slide in the direction of the arrow A3 or in the direction of the arrow A4 while each of the outer peripheral surfaces thereof is closely attached to the seal ring 100. The seal ring 100 suppresses the coolant CL from passing between the socket outer cylinder 86 and the plug inner cylinder 80 when in the connected state.

Moreover, as illustrated in FIG. 1A, in the coolant supply member 52, the connecting plug 72 is attached to the supply passage 38 so as to function as a supply-purpose connection member 58, and the connecting socket 74 is attached to the first coolant member 28 so as to function as a supply-side connection member 56. In the coolant discharge member 54, the connecting plug 72 is attached to the first coolant member 28 so as to function as a discharge-side connection member 60, and the connecting socket 74 is attached to the discharge passage 40 so as to function as a discharge-purpose connection member 62. In the coolant transport member 32, the connecting plug 72 is attached to the first coolant member 28, and the connecting socket 74 is attached to the second coolant member 30. In the coolant transport member 34, the connecting plug 72 is attached to the second coolant member 30, and the connecting socket 74 is attached to the first coolant member 28.

Note that the shapes and sizes of the connecting plug 72 and the connecting socket 74 are adjusted as appropriate in accordance with where they are used.

As illustrated in FIGS. 5 and 6, the system substrate body 18 includes a plurality of substrate units 12 that are mounted on a single system substrate 20. In the system substrate body 18 of the first embodiment, a plurality of substrate units 12 are mounted in a row or rows on the system substrate 20 so as to form a single or a plurality of mount arrays 102 (two arrays in the illustrated example).

The substrate units 12 are provided so that they are perpendicular to the system substrate 20 in an erect manner such that the substrate units 12 are parallel to each other in each of the mount arrays 102. In the substrate unit 12, the package substrate 14, the first coolant member 28, and the second coolant member 30 are parallel to each other; accordingly, in the entire system substrate body 18, all of the package substrates 14, the first coolant members 28, and the second coolant members 30 are arranged parallel to each other. Furthermore, in each of the mount arrays 102, each of the package substrates 14 are arranged so as to overlap each other when viewed in the direction normal to the package substrates 14.

As illustrated in FIG. 7, an electronic device 104 includes a housing 106. The system substrate body 18 is arranged inside the housing 106.

Furthermore, the circulation passages 44 are arranged inside the housing 106, and circulation routes 108, through which the coolant CL is circulated, are formed with the circulation passages 44, the supply passages 38, and the discharge passages 40.

A pump 46, a tank 48, and a cooling device 50 are provided in the circulation passages 44. By driving the pump 46, the coolant CL may be circulated in the circulation routes 108.

The tank 48 is capable of retaining a portion of the coolant CL. The cooling device 50 is capable of cooling the coolant CL discharged from each of the substrate units 12.

A function of the first embodiment will be described next. In the substrate unit 12 that includes the cooling structure 16, the first coolant member 28 is in contact with the first heat generating elements 22 on the one surface 14A of the package substrate 14, and the second coolant member 30 is in contact with the second heat generating elements 24 on the other surface 14B. Moreover, as illustrated in FIG. 7, the pump 46 is driven such that the coolant CL that has been cooled by the cooling device 50 flows into the supply passages 38. Furthermore, as illustrated in FIGS. 1A to 1C, the coolant CL is supplied to and flows in the flow space 36 of the first coolant member 28 and the flow space 66 of the second coolant member 30. Accordingly, the heat generating elements mounted on both sides of the package substrate 14 may be effectively cooled.

In particular, regarding the first heat generating elements 22, the coolant CL that has been cooled is supplied to and flows in the flow space 36 of the first coolant member 28. Accordingly, in the case of cooling the first heat generating elements 22, compared with a structure in which no coolant CL is supplied, the first heat generating elements 22 may be cooled in an effective manner.

Furthermore, in the first embodiment, regarding the second heat generating elements 24, the coolant CL that has been cooled is supplied to and flows in the flow space 66 of the second coolant member 30 through the first coolant member 28. Accordingly, in the case of cooling the second heat generating elements 24, compared with a structure in which no coolant CL is supplied, the second heat generating elements 24 may be cooled in an effective manner.

The coolant CL, whose temperature has been increased by the heat of the first heat generating elements 22 and the second heat generating elements 24, is discharged to the outside of the cooling structure 16 and a new coolant CL is supplied to the inside of the cooling structure 16 (the flow space 36). Accordingly, the first heat generating elements 22 and the second heat generating elements 24 may be continuously cooled.

In the first embodiment, the coolant CL flows between the first coolant member 28 and the second coolant member 30 through the coolant transport members 32 and 34. In other words, the coolant CL that has been supplied to the first coolant member 28 may be supplied to the second coolant member 30 as well; accordingly, the second coolant member 30 may cool the second heat generating element 24. Furthermore, the coolant CL, whose temperature has been increased by the heat of the second heat generating elements 24, may be discharged through the first coolant member 28.

In the first embodiment, the coolant transport member 32 includes the connecting plug 72 that is attached to the first coolant member 28 and the connecting socket 74 that is attached to the second coolant member 30. Furthermore, the coolant transport member 34 includes the connecting plug 72 that is attached to the second coolant member 30 and the connecting socket 74 that is attached to the first coolant member 28. Accordingly, the connecting plugs 72 and the connecting sockets 74 may be connected to each other by moving the first coolant member 28, from the one surface 14A side, and the second coolant member 30, from the other surface 14B side, close to each other such that the package substrate 14 is arranged between the first coolant member 28 and the second coolant member 30. As described above, a structure that is capable of moving the coolant CL between the first coolant member 28 and the second coolant member 30 may be provided by arranging the package substrate 14 between the first coolant member 28 and the second coolant member 30 and connecting the connecting plugs 72 and the connecting sockets 74 to each other.

The first coolant member 28 is in contact with an entire surface of each of the two first heat generating elements 22. Accordingly, compared with a structure in which the first coolant member 28 is in contact with a portion of the other surface 22S of either one of the first heat generating elements 22, a greater cooling effect is exerted on the first heat generating elements 22.

Similarly, the second coolant member 30 is in contact with an entire surface of each of the two second heat generating elements 24. Accordingly, compared with a structure in which the second coolant member 30 is in contact with a portion of the other surface 24S of either one of the second heat generating elements 24, a greater cooling effect is exerted on the second heat generating element 24.

In the cooling structure 16, the coolant transport members 32 and 34 pass through the through holes 68 of the package substrate 14. Accordingly, compared with a structure in which the coolant transport members 32 and 34 do not penetrate the package substrate 14 and are arranged on the outside with respect to the edge portion 14E of the package substrate 14, the coolant transport members 32 and 34 do not bulge out and the cooling structure 16 may be made smaller.

In the cooling structure 16, the direction in which the supply-side connection member 56 is connected to the supply-purpose connection member 58 and the direction in which the discharge-side connection member 60 is connected to the discharge-purpose connection member 62 are the same (the direction of the arrow A1 illustrated in FIG. 1A). Accordingly, when the cooling structure 16 is connected to the system substrate 20, the connection of the supply-side connection member 56 to the supply-purpose connection member 58 and the connection (connecting of the connection members) of the discharge-side connection member 60 to the discharge-purpose connection member 62 may be carried out in a single sequence; accordingly, connection is facilitated.

The package substrate 14 includes the electrical connector 26. By electrically coupling the electrical connector 26 to the external device connector 64 of the system substrate 20, transfer of electric signals and power may be carried out between the package substrate 14 and the system substrate 20.

Furthermore, in the substrate unit 12, the direction in which the electrical connector 26 is connected to the external device connector 64 and the direction in which the supply-side connection member 56 is connected to the supply-purpose connection member 58 are the same (the direction of the arrow A1). When the substrate unit 12 is mounted on the system substrate 20, in addition to the above-described connection of the cooling-liquid communicating member 70, the connection of the electrical connector 26 to the external device connector 64 may be carried out in a single sequence as well.

The tabular first coolant member 28 and second coolant member 30 are parallel to the tabular package substrate 14. Accordingly, compared with a structure in which at least either one of the first coolant member 28 and the second coolant member 30 is not parallel to the package substrate 14, a thickness T1 (see FIG. 6) of the substrate unit 12 as a whole may be suppressed.

As illustrated in FIGS. 5 and 6, in the system substrate body 18, the plurality of substrate units 12 are mounted on the system substrate 20 in a perpendicular and erect manner. For example, compared with a structure in which the package substrate 14 is mounted on the system substrate 20 in a parallel manner with respect to the system substrate 20, a mounting area per each substrate unit 12 may be small; accordingly, the substrate units 12 may be mounted with high density.

In addition, the substrate unit 12 is structured so that the coolant CL is directly supplied to the first coolant member 28; accordingly, a member for exchanging heat does not have to be provided between the first coolant member 28 and the other members. Since a member for exchanging heat does not have to be provided, the substrate units 12 may be arranged close to each other; accordingly, the substrate units 12 may be mounted with high density.

Furthermore, the tabular first coolant member 28 and the second coolant member 30 that also has a tabular shape are arrange parallel to the package substrate 14. Accordingly, compared with a structure in which the first coolant member 28 and the second coolant member 30 do not have a tabular shape, the substrate units 12 may be arranged close to each other; accordingly, the substrate units 12 may be mounted with high density.

In particular, the plurality of substrate units 12 in each mount array 102 is mounted so that the package substrates 14 are parallel to each other. Accordingly, compared with a structure in which the substrate units 12 are mounted on the system substrate 20 such that the package substrates 14 are not parallel to each other, the space between the substrate units 12 may be uniform and small; accordingly, the substrate units 12 may be mounted with high density.

Moreover, in each mount array 102, the package substrates 14 overlap each other when viewed in a direction normal to the package substrate 14. Accordingly, compared with a structure in which the package substrates 14 do not overlap each other when viewed in a direction normal to the package substrate 14, a width W1 (see FIG. 6) of the mount array 102 is small; accordingly, the substrate units 12 may be mounted with high density.

The system substrate 20 is provided with the supply passages 38 and the discharge passages 40 of the coolant CL. The coolant CL may be supplied to the first coolant member 28 through the supply passage 38. Furthermore, the coolant CL may be discharged from the first coolant member 28 through the discharge passage 40 and may be collected.

In particular, in the first embodiment, a single mount array 102 is provided with only a single supply passage 38 and a single discharge passage 40. Since the plurality of substrate units 12 of a single mount array 102 share a supply passage 38 and a discharge passage 40, compared to a structure in which a plurality of substrate units 12 are each provided with a supply passage and a discharge passage, the structure may be simple.

Furthermore, as can be seen in FIG. 7, the supply passages 38 are arranged so as to be side by side with each other in the two mount arrays 102. Accordingly, the two circulation passages 44 may be arranged close to each other at certain portions, and the flow direction of the coolant CL may be the same in the portions close to each other. As described above, by arranging the pump 46, the tank 48, and the cooling device 50 in the two circulation passages 44 that are arranged close to each other, the two circulation routes 108 may share the pump 46, the tank 48, and the cooling device 50.

As illustrated in FIG. 7, the system substrate body 18 includes a circulation device (the pump 46) and the cooling device 50. The coolant CL may be made to circulate in the circulation routes 108 with the circulation device. Furthermore, the cooling device 50 is capable of reducing the coolant CL temperature that has been increased after being used for cooling. Accordingly, the coolant CL inside the first coolant member 28 (the flow space 36) and the second coolant member 30 (the flow space 66) may be replaced with a coolant CL with a lower temperature, thus, the cooling capacity of the first coolant member 28 and the second coolant member 30 may be maintained.

Since the electronic device 104 includes a system substrate body 18, the heat generating elements (the first heat generating elements 22 and the second heat generating elements 24) on both sides of the package substrate 14 may be cooled effectively and the package substrate 14 may be arranged with high density.

Subsequently, a second embodiment to a fifth embodiment will be described. In each of the following embodiments, since the overall configurations of the system substrate body and the electronic device are substantially the same, illustration of these is omitted. Furthermore, in each of the following embodiments, elements, components, and the like that are the same as those of the first embodiment are denoted with the same reference numerals and detailed descriptions thereof are omitted.

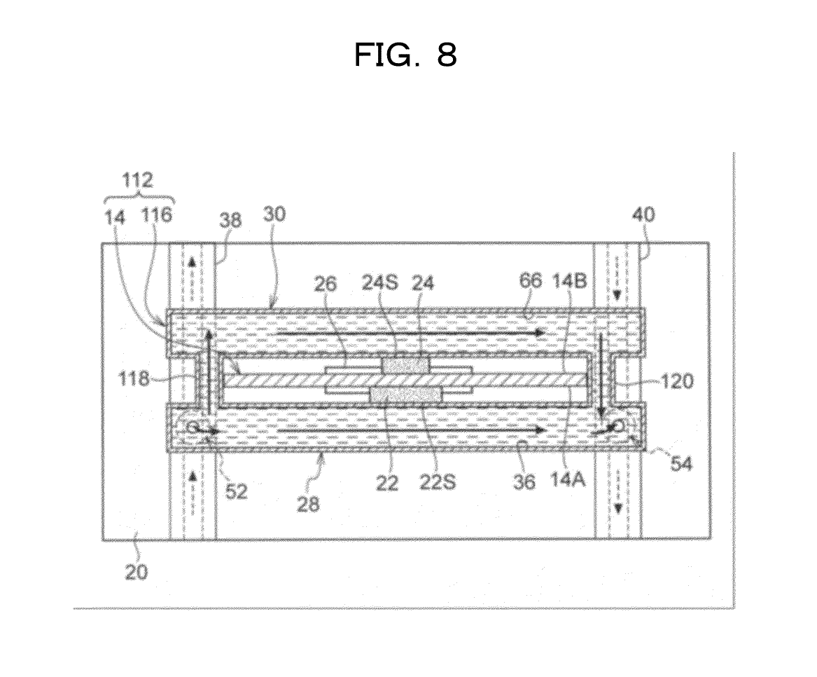

FIG. 8 illustrates a cooling structure 116 and a substrate unit 112 of the second embodiment.

In the second embodiment, liquid communicating tubes 118 and 120 are provided in place of the coolant transport members 32 and 34 of the first embodiment. The liquid communicating tubes 118 and 120 are integrally formed with the first coolant member 28 and the second coolant member 30. Accordingly, the first coolant member 28 and the second coolant member 30 are integrally formed with the liquid communicating tubes 118 and 120.

The liquid communicating tubes 118 and 120 are both cylindrical allowing the coolant CL to flow there through. Accordingly, the coolant CL may flow between the first coolant member 28 and the second coolant member 30. Both of the liquid communicating tubes 118 and 120 are examples of a coolant transport member and, further, are examples of a connection member.

In the second embodiment having such a structure, the liquid communicating tubes 118 and 120 (connection members) are integrally formed with the first coolant member 28 and the second coolant member 30; accordingly, the structure is simple compared with the first embodiment.

Note that in the second embodiment, since the liquid communicating tubes 118 and 120 are integrally formed with the first coolant member 28 and the second coolant member 30, it is difficult to have a structure in which the liquid communicating tubes 118 and 120 penetrate the package substrate 14. However, as can be seen in FIG. 8, the liquid communicating tubes 118 and 120 may be positioned on the outside of the outer edge of the package substrate 14 (the outer edge on the lateral side in the illustrated example).

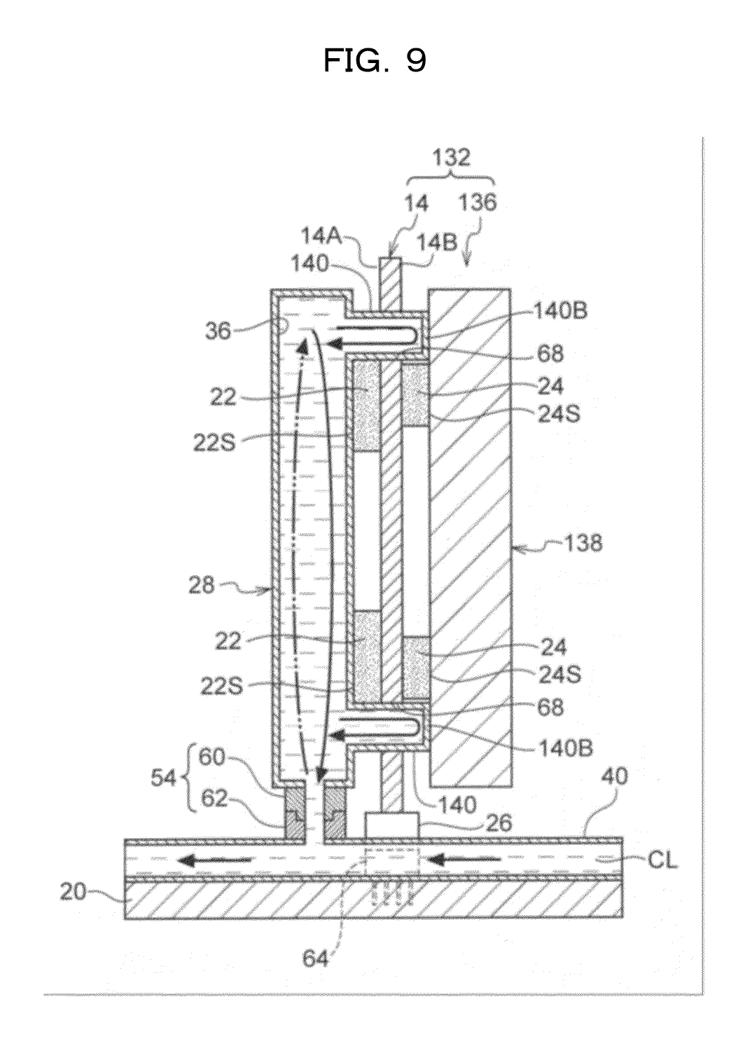

FIG. 9 illustrates a cooling structure 136 and a substrate unit 132 of the third embodiment.

In the third embodiment, a heat conducting member 138 is provided in place of the second coolant member 30 of the first embodiment. The heat conducting member 138 is made of metal and is formed in a tabular shape in the illustrated example. In the third embodiment, the heat conducting member 138 is formed with a size that allows the heat conducting member 138 to be in contact with the entire surface of the other surfaces 24S of the two second heat generating elements 24. The heat conducting member 138 is an example of the second cooling member.

Note that in the third embodiment and the fourth embodiment described later, examples are given in which two through holes 68 are provided in the package substrate 14, specifically, one in the upper portion and one in the lower portion of the package substrate 14. The number and position of the through holes 68 are not limited in particular. For example, a total of four through holes 68, each in the vicinity of the corner portions of the package substrate 14 when viewed in the direction normal to the package substrate 14 (in the direction of the arrow A1), may be formed. Furthermore, similar to the third embodiment, in the first and second embodiments, a through hole 68 may be formed on the upper portion and the lower portion of the package substrate 14.

Projections 140 are formed in the first coolant member 28 at positions corresponding to the two through holes 68 of the package substrate 14. The projections 140 are each formed in a cylindrical shape, and the tip portion of each projection 140 is closed with a bottom plate 140B. The inside of each projection 140 is in communication with the flow space 36 of the first coolant member 28. The coolant CL circulates inside each projection 140.

The projection length of each projection 140 is determined so that the tip (bottom plate 140B) of the projection 140 is in contact with the heat conducting member 138 when the first coolant member 28 is in contact with the first heat generating element 22 and when the heat conducting member 138 is in contact with the second heat generating element 24.

In the third embodiment with the above-described structure, similar to the first embodiment, the first heat generating element 22 may be cooled with the first coolant member 28.

Furthermore, in the third embodiment, the heat of the second heat generating elements 24 is conducted to the heat conducting member 138. Since the heat conducting member 138 is made of metal, thermal conductivity is high compared to, for example, resin and the like and heat is diffused to the entire heat conducting member 138 more easily. The bottom plate 140B of each projection 140 of the first coolant member 28 is in contact with the heat conducting member 138 and, further, the coolant CL circulates inside each projection 140. Accordingly, the projections 140 is capable of cooling the heat conducting member 138. In other words, the heat that the heat conducting member 138 has received from the second heat generating element 24 is easily transported to the projections 140. Furthermore, the heat of the heat conducting member 138 is transported to the coolant CL through the projections 140. Accordingly, compared with a structure that has no projection 140 (or a structure in which the projections 140 do not come in contact with the heat conducting member 138), the heat conducting member 138 exerts a greater cooling effect on the second heat generating element 24.

Furthermore, since in the third embodiment, the coolant transport members 32 and 34 can be disposed of, compared with the first embodiment, the number of parts may be small and a reduction of cost may be achieved.

Note that in the third embodiment, the portions in the heat conducting member 138 that are in contact with the projections 140 do not have to be flat. For example, some portions of the heat conducting member 138 may be projections that project towards the projections 140. In such a case, the projection length of the projections 140 may be shortened. Furthermore, some portions of the heat conducting member 138 may be dented so that the tip of each projection 140 is partially received by the dent.

Similarly, the bottom plate 140B of each projection 140 does not have to have a flat shape. However, if the portions of the bottom plate 140B of the projection 140 and the heat conducting member 138 that are in contact with each other are planar, compared with a structure in which the bottom plate 140B and the heat conducting member 138 make contact with each other in a dotted manner, the contact area may be large and there is an advantage in that the thermal conductivity is increased.

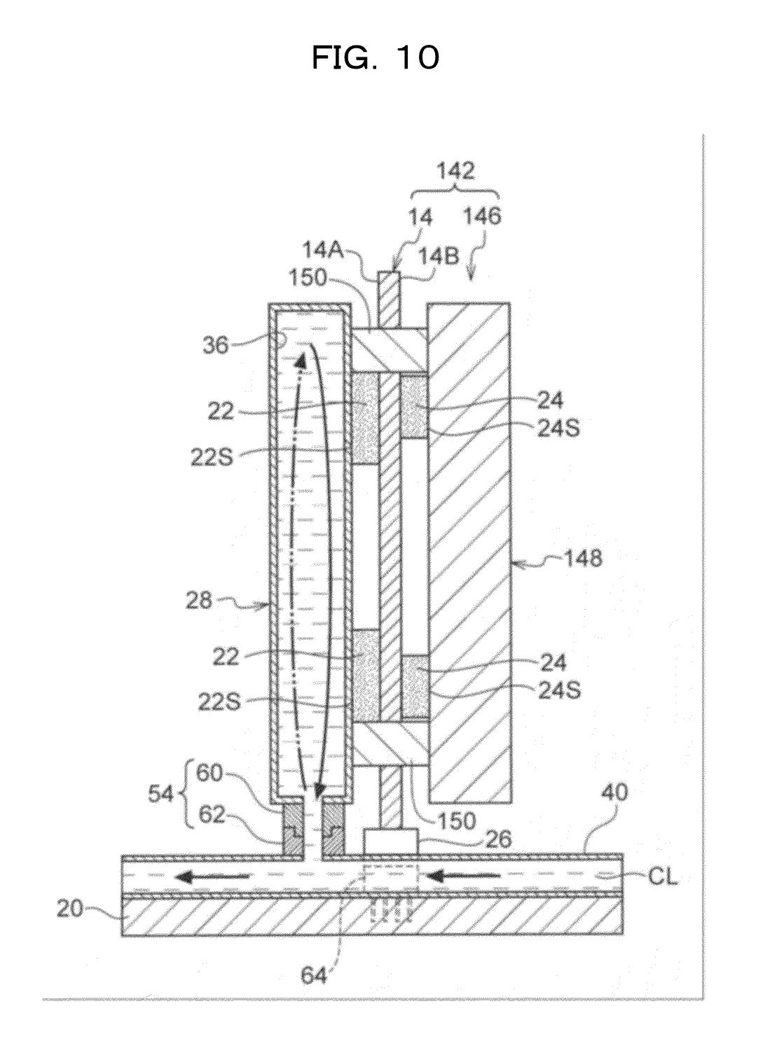

FIG. 10 illustrates a cooling structure 146 and a substrate unit 142 of the fourth embodiment.

In the fourth embodiment, a heat conducting member 148 is provided in place of the second coolant member 30 of the first embodiment. The heat conducting member 148 of the fourth embodiment has, similar to the heat conducting member 138 of the third embodiment, a tabular shape made of metal. The heat conducting member 148 is formed with a size that allows the heat conducting member 148 to be in contact with the entire surface of the other surfaces 24S of the two second heat generating elements 24 and is an example of the second cooling member.

Contact members 150 that are inserted into the two through holes 68 of the package substrate 14 are arranged between the first coolant member 28 and the heat conducting member 148. The contact members 150 is formed of metal, for example, and is in contact with both the first coolant member 28 and the heat conducting member 148. Note that the metal portion of the contact member 150 may be solid inside; however, the metal portion may be formed so as to be hollow inside and a liquid may be filled therein, for example, and heat may be transported by repeating an evaporation and condensation cycle with the liquid.

In the fourth embodiment having such a structure, similar to the first embodiment, the first heat generating elements 22 may be cooled by the first coolant member 28.

Furthermore, in the fourth embodiment, the heat of the second heat generating elements 24 is conducted to the heat conducting member 148. Since the heat conducting member 148 is made of metal, thermal conductivity is high compared to, for example, resin and the like and heat is diffused to the entire heat conducting member 148 more easily. The heat conducting member 148 is in contact with the contact members 150 and, further, the contact members 150 are in contact with the first coolant member 28. Accordingly, the heat of the heat conducting member 148 may be transported to the first coolant member 28 through the contact members 150. In other words, the heat that the heat conducting member 148 has received from the second heat generating elements 24 is easily transported to the first coolant member 28 through the contact members 150. Accordingly, compared with a structure in which the heat of the heat conducting member 148 is not transported to the first coolant member 28 through the contact members 150, the heat conducting member 148 has a greater cooling effect on the second heat generating element 24.

In the fourth embodiment, since the contact members 150 are interposed between the first coolant member 28 and the heat conducting member 148, the structure connecting the first coolant member 28 and the heat conducting member 148 in a manner allowing heat to be transported therebetween, in particular, a structure of the first coolant member 28, may be simplified; accordingly, cost reduction may be achieved.

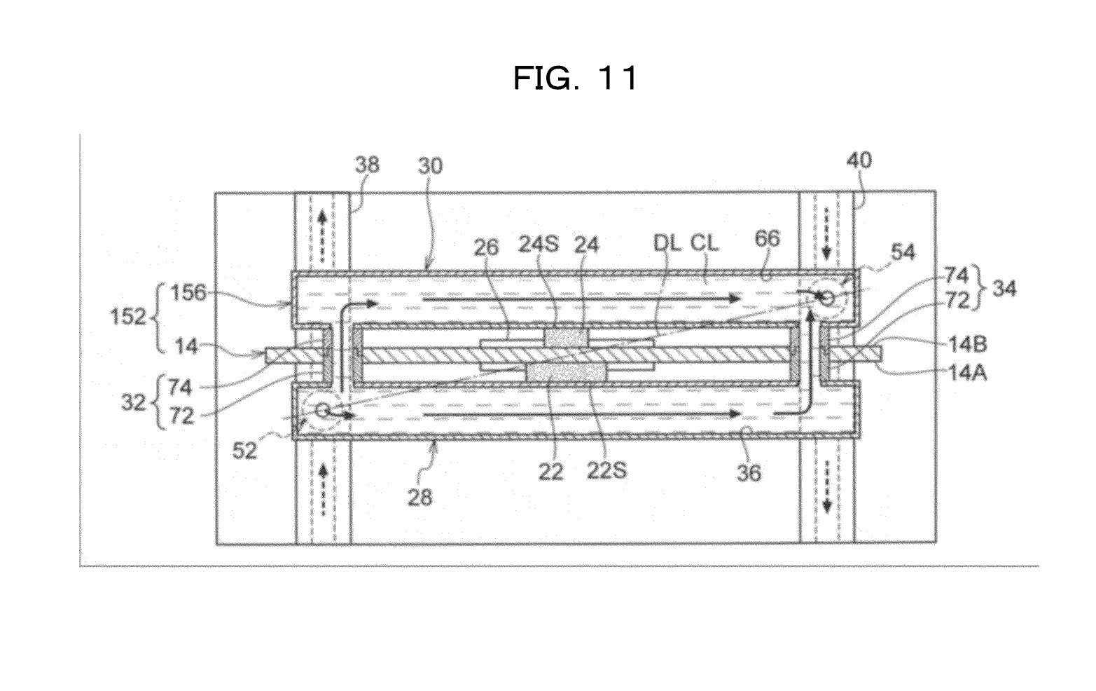

FIG. 11 illustrates a cooling structure 156 and a substrate unit 152 of the fifth embodiment.

Similar to the first embodiment, the fifth embodiment includes the first coolant member 28 and the second coolant member 30; however, the position of the coolant discharge member 54 is not under the first coolant member 28 but is under the second coolant member 30. In other words, the positions of the discharge-side connection member 60 and the discharge-purpose connection member 62 (see FIG. 1A and the like that illustrate both members in the first embodiment) are set so that the coolant discharge member 54 is positioned under the second coolant member 30.

Furthermore, the direction of the coolant transport member 34 is opposite to that in the first embodiment, and the coolant CL flows from the first coolant member 28 towards the second coolant member 30.

In the fifth embodiment having such a structure, the coolant CL is supplied from the supply passage 38 to the first coolant member 28 and, further, the coolant CL flows from the first coolant member 28 to the second coolant member 30 through both of the coolant transport members 32 and 34. Then, the coolant CL is discharged from the second coolant member 30 to the discharge passage 40.

In the fifth embodiment, a line DL that connects the coolant supply member 52 and the coolant discharge member 54 when the substrate unit 152 is viewed from above as in FIG. 11 passes through the center portion or near the center portion of the substrate unit 152. Moreover, the substrate unit 152 is supported by the coolant supply member 52 on the first coolant member 28 side and the coolant discharge member 54 on the second coolant member 30 side. Accordingly, the substrate unit 152 maybe mounted on the system substrate 20 in a stable manner.

As described above, in either of the second to fifth embodiments, the first heat generating elements 22 that are provided on the one surface 14A of the package substrate 14 are in contact with the first coolant member 28, and the second heat generating elements 24 that are provided on the other surface 14B are in contact with the second cooling member (the second coolant member 30, the heat conducting member 138, or the heat conducting member 148). Furthermore, as illustrated in FIG. 7, the pump 46 is driven so that the coolant CL that has been cooled by the cooling device 50 is supplied and flows in the flow space 36 of the first coolant member 28 and the flow space 66 of the second coolant member 30. Accordingly, the heat generating elements that are mounted on both sides of the package substrate 14 may be effectively cooled.

In each of the system substrate bodies of the first to fifth embodiments described above, the arrangement of the package substrates 14 in the substrate units are not limited to an arrangement in which all of the package substrates 14 are parallel to each other. In other words, as long as at least two package substrates 14 in the substrate units are arranged parallel to each other, compared to a structure in which the package substrates 14 are arranged in a non-parallel manner, the substrate units may be mounted with high density on the system substrate body.

The electronic device of the present application is not limited to a specific electronic device and may be any electronic device that includes a system substrate body having a system substrate on which a plurality of substrates are mounted. Large computers, servers, and other devices are examples of the electronic device.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A substrate unit, comprising:
a substrate arranged with a first heat generating element on one surface and a second heat generating element on the other surface;
a first cooler that is arranged on one surface side of the substrate and that is in contact with the first heat generating element, the first cooler having a coolant flowing therein;
a second cooler that is arranged on the other surface side of the substrate and that is in contact with the second heat generating element, the second cooler having the coolant flowing therein;
a supply port provided in the first cooler, the supply port supplying the coolant to the first cooler;
a discharge port provided in the first cooler, the discharge port discharging the coolant in the first cooler; and
transport tubes that are connected to the first cooler and the second cooler, the transport tubes allowing the coolant to be transported between the first cooler the second cooler.

2. The substrate unit according to claim 1, wherein
the transport tube is in communication with inside of the first cooler and inside of the second cooler, the transport tube including a space through which the coolant travels.

3. The substrate unit according to claim 2, wherein
the transport tube is integrally formed with the first cooler and the second cooler.

4. The substrate unit according to claim 1, wherein
the first cooler has a shape that comes in contact with an entire surface of the first heat generating element, and
the second cooler has a shape that comes in contact with an entire surface of the second heat generating element.

5. The substrate unit according to claim 1, wherein
the first cooler and the second cooler are arranged parallel to the substrate.

6. The substrate unit according to claim 1, wherein
the supply port and the discharge port are provided in the same surface of the first cooler

7. The substrate unit according to claim 1, wherein
the transport tube includes
a first transport tube that transports the coolant inside the first cooler to the second cooler, and
a second transport tube that transports the coolant inside the second cooler to the first cooler.

8. An electronic device, comprising:
a system substrate; and
a plurality of substrate units that is mounted over the system substrate in an erect manner, each substrate unit including
a substrate arranged with a first heat generating element on one surface and a second heat generating element on the other surface,
a first cooler that is arranged on one surface side of the substrate and that is in contact with the first heat generating element, the first cooler having a coolant flow therein,
a second cooler that is arranged on other surface side of the substrate and that is in contact with the second heat generating element, the second cooler having the coolant flow therein,
a supply port provided in the first cooler, the supply port supplying the coolant to the first cooler,
a discharge port provided in the first cooler, the discharge port discharging the coolant in the first cooler, and
transport tubes that are connected to the first cooler and the second cooler, the transport tubes allowing the coolant to be transported between the first cooler and the second cooler.

9. The electronic device according to claim 8, further comprising:
a supply passage that is connected to the supply port of the first cooler of each substrate unit, the supply passage supplying the coolant to the first cooler; and
a discharge passage that is connected to the discharge port of the first cooler of each substrate unit, the discharge passage discharging the coolant in the first cooler.

10. The electronic device according to claim 9, further comprising:
a pump that sends out the coolant to the supply passage; and a cooling device that cools the coolant that has been discharged from the discharge passage.

11. The electronic device according to claim 10, further comprising:
a tank that is provided between the pump and the cooling device, the tank retaining the coolant.

12. The electronic device according to claim 8, wherein
the plurality of substrate units are mounted on the system substrate in an erect manner such that the plurality of substrate units are parallel to each other.
